(19) United States
(12) Patent Application Publication
(10) Pub. No.: US 2023/0217671 A1
(43) Pub. Date: Jul. 6, 2023

(54) WHITE LIGHT EMITTING DEVICE AND DISPLAY DEVICE USING THE SAME

(71) Applicant: LG Display Co., Ltd., Seoul (KR)

(72) Inventors: Hee Young CHAE, Paju-si (KR); Seung Ryong JOUNG, Paju-si (KR); Jeong Eun WON, Paju-si (KR); Yoon Deok HAN, Paju-si (KR); Hee Su BYEON, Paju-si (KR)

(73) Assignee: LG Display Co., Ltd., Seoul (KR)

(21) Appl. No.: 18/090,022

(22) Filed: Dec. 28, 2022

(30) Foreign Application Priority Data
Dec. 31, 2021 (KR) 10-2021-0194796
Dec. 20, 2022 (KR) 10-2022-0179881

(51) Int. Cl. H10K 50/13; H10K 50/16; H10K 59/121; H10K 59/35; H10K 59/80

(52) U.S. Cl. CPC H10K 50/13; H10K 50/16; H10K 59/351; H10K 59/879; H10K 59/1213; H10K 59/80524; H10K 2102/103

(57) ABSTRACT

A white light emitting device, or more particularly an inverted white light emitting device, includes a plurality of stacks configured to emit white light, and an optical compensation layer provided at an outer surface of an electrode through which light is emitted to the outside. The configuration reduces the thickness of an electron transport layer adjacent to a cathode in the stack and therefore reduces the driving voltage and improves the viewing angle characteristics and as well as the efficiency.

### CROSS-REFERENCE TO RELATED APPLICATION

This application claims the benefit of and priority to Korean Patent Application No. 10-2021-0194796, filed on Dec. 31, 2021 and Korean Patent Application No. 10-2022-0179881, filed on Dec. 20, 2022, the entirety of each of which is incorporated herein by reference for all purposes as if fully set forth herein.

### BACKGROUND

### 1. Technical Field

The present disclosure relates to display devices, light emitting devices and methods and particularly to, for example, without limitation, a white light emitting device and a display device using the white light emitting device.

### 2. Discussion of the Related Art

In recent years, a self-emissive display device has been developed to provide a compact device with a vivid color display without the need to have a separate light source. Depending on the internal light emitting material used, a self-emissive display device may be classified as an organic light emitting display device or an inorganic light emitting display device.

A self-emissive display device includes a plurality of subpixels, wherein each subpixel is provided with a light emitting element without a separate light source in order to emit light to the outside.

In addition, for a display device with high resolution and high integration capabilities, a tandem device having an organic layer and an emission layer without requiring a metal micromask has been explored in terms of processability, and research thereon has been conducted.

In recent years, an inverted light emitting device has been considered to simplify its circuit configuration so that an emission portion of the light emitting display device may be increased. When a plurality of stacks is provided between both electrodes of the inverted light emitting device, however, the thickness of an electron transport layer is increased in order to adjust the emission position of an emission layer in the lowest stack. When the thickness of the electron transport layer, which has a low mobility, is increased, the driving voltage is increased, and the viewing angle characteristics are deteriorated due to the increase in thickness of the stack.

The description provided in the discussion of the related art section should not be assumed to be prior art merely because it is mentioned in or associated with that section. The discussion of the related art section may include information that describes one or more aspects of the subject technology.

### SUMMARY

The inventors of the present disclosure have recognized the problems and disadvantages of the related art and have performed extensive research and experiments. The inventors of the present disclosure have thus invented new white light emitting devices and display devices using the same that substantially obviate one or more problems due to limitations and disadvantages of the related art.

Additional features, objects, advantages, and aspects of the present disclosure are set forth in part in the description that follows and in part will become apparent from the present disclosure or may be learned by practice of the inventive concepts provided herein. Other features, objects, advantages, and aspects of the present disclosure may be realized and attained by the descriptions provided in the present disclosure, or derivable therefrom, and the claims hereof as well as the appended drawings. It is intended that all such features, objects, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

To achieve these objects and other advantages of the present disclosure, in one or more aspects, a light emitting element, or more particularly an inverted white light emitting device, is configured such that a structure adjacent to an electrode through which light is emitted to the outside is changed, whereby a driving voltage is reduced and the efficiency and viewing angle characteristics are improved, and a display device using the same may be provided.

It is to be understood that both the foregoing description and the following description of the present disclosure are exemplary and explanatory, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate embodiments of the disclosure, and together with the description serve to explain principles of the disclosure. In the drawings:

FIG. 1 is a sectional view showing a white light emitting device according to an example embodiment of the present disclosure;

FIG. 2 and FIG. 3 are sectional views showing one subpixel of display devices according to various example embodiments of the present disclosure;

FIG. 4 is an example of a circuit diagram of one subpixel of a display device having the white light emitting device of FIG. 1;

FIG. 5 is a sectional view schematically showing an optical functional layer of the display device according to one or more example embodiments of the present disclosure;

FIGS. 6A and 6B are examples of sectional views showing white light emitting devices used in a first experimental example and a second experimental example;

FIGS. 7A to 7C are examples of sectional views showing third to fifth experimental examples;

FIG. 8 is an example of a sectional view showing a sixth experimental example;

FIG. 9 is an example of a graph showing white spectra of the first to sixth experimental examples;

FIGS. 10A to 10C are examples of sectional views showing seventh to ninth experimental examples;

FIG. 11 is an example of a sectional view showing a tenth experimental example;

FIG. 12 is an example of a graph showing white spectra of first and second experimental modifications and the seventh to tenth experimental examples;

FIG. 13 is a sectional view showing a display device according to another example embodiment of the present disclosure;

FIGS. 14A to 14D are examples of graphs respectively showing the relationship between red, green, blue, and white efficiencies and the thickness of an optical compensation layer; and

FIG. 15 is a sectional view showing a white light emitting device according to another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known functions or configurations may unnecessarily obscure aspects of the present disclosure, the detailed description thereof may be omitted. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are provided so that this disclosure is thorough and complete and fully conveys the scope of the present disclosure to those skilled in the art. Furthermore, the present disclosure is only defined by claims and their equivalents.

The shapes, sizes, areas, ratios, angles, numbers, and the like disclosed in the drawings for describing embodiments of the present disclosure are merely examples, and thus, the present disclosure is not limited to the illustrated details.

When the term “comprise,” “have,” “include,” “contain,” “constitute,” “make up of,” “formed of,” or the like is used, one or more other elements may be added unless a term such as “only” or the like is used. The terms used in the present disclosure are merely used in order to describe particular embodiments, and are not intended to limit the scope of the present disclosure. The terms of a singular form may include plural forms unless the context clearly indicates otherwise. The word “exemplary” is used to mean serving as an example or illustration. Embodiments are example embodiments. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship, where the positional relationship between two parts is described, for example, using “on,” “over,” “under,” “above,” “below,” “beneath,” “near,” “close to,” or “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the terms “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various embodiments of the present disclosure may be partially or wholly coupled to or combined with each other and may be variously inter-operated, linked or driven together. The embodiments of the present disclosure may be carried out independently from each other or may be carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” may apply, for example, to a separate circuit or structure, an integrated circuit, a computational block of a circuit device, or any structure configured to perform a described function as should be understood by one of ordinary skill in the art.

Hereinafter, various example embodiments of the present disclosure are described in detail with reference to the accompanying drawings. For convenience of description, a scale, dimension, size, and thickness of each of the elements illustrated in the accompanying drawings may differ from an actual scale, dimension, size, and thickness, and thus, embodiments of the present disclosure are not limited to a scale, dimension, size, and thickness illustrated in the drawings.

In this present disclosure, an electroluminescence (EL) spectrum may be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

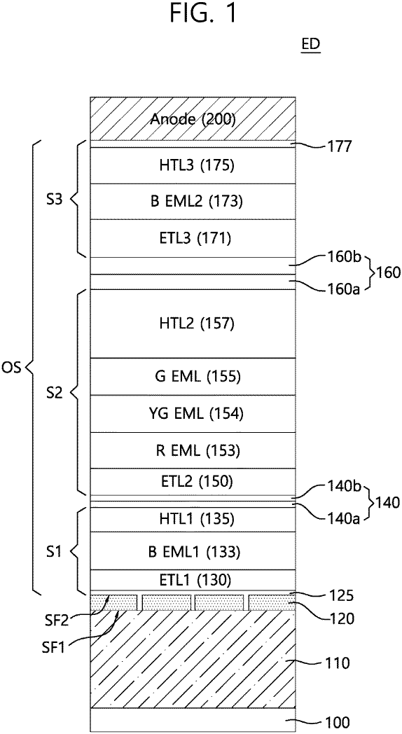

FIG. 1 is a sectional view showing a white light emitting device according to an example embodiment of the present disclosure.

As shown in FIG. 1, the white light emitting device ED according to an example embodiment of the present disclosure may include an optical compensation layer 110 on a substrate 100, a cathode 120 having a first surface SF1 abutting the optical compensation layer 110, an anode 200 opposite to a second surface SF2 of the cathode 120, and an intermediate functional layer OS disposed between the second surface SF2 of the cathode 120 and the anode 200. The intermediate functional layer OS may include a plurality of stacks S1, S2, and S3 divided by charge generation layers 140 and 160. The intermediate functional layer OS may be configured to emit white light.

In an example embodiment of the present disclosure, the intermediate functional layer OS is located particularly between the cathode 120 and the anode 200 that are opposite to each other, and is so named since the intermediate functional layer OS includes an emission layer, which has a light emitting function.

In FIG. 1, the intermediate functional layer OS is shown as including three stacks; however, the present disclosure is not limited thereto. The intermediate functional layer OS may include two or more stacks having a charge generation layer therebetween (e.g., a charge generation layer may be provided between every two stacks). Consequently, the intermediate functional layer OS may be a three-stack structure, as shown, a two-stack structure, or a structure including four or more stacks.

In one or more examples, as a minimum configuration, the intermediate functional layer OS may include a first stack S1 including a first blue emission layer 133 and a second stack S2 including first to third emission layers 153, 154, and 155 configured to emit lights having different wavelengths longer than the wavelength of the blue light.

As an example, the second stack S2 may include a red emission layer 153, a yellowish green emission layer 154, and a green emission layer 155.

Further, as shown in FIG. 1, the intermediate functional layer OS may further include a third stack S3 including a second blue emission layer 173, in addition to the minimum configuration.

The plurality of stacks included in the intermediate functional layer OS may be divided by the charge generation layers 140 and 160, and each stack may include one or more emission layers. In order to emit white light, the first stack S1, which emits the blue light, and the second stack S2, which emits lights having wavelengths longer than the wavelength of the blue light, are included in the intermediate functional layer OS. In order to improve efficiency, a stack having the same structure as the first stack S1 and/or the second stack S2 may be further included in the intermediate functional layer OS.

Depending on the circumstances, the added stack other than the first and second stacks S1 and S2 may include a blue emission layer and another color emission layer abutting the blue emission layer in order to further improve blue light efficiency. The stack including the blue emission layer and the other color emission layer abutting the blue emission layer may be provided when three or more stacks are included.

In addition, the stacks may respectively include first to third electron transport layers 130, 150, and 171 disposed under the first blue emission layer 133, the red emission layer 153, and the second blue emission layer 173, respectively. The first to third electron transport layers 130, 150, and 171 may be configured to transport electrons to the emission layers 133, 153/154/155, and 173, respectively. The stacks may respectively include first to third hole transport layers 135, 157, and 175 disposed on the first blue emission layer 133, the green emission layer 155, and the second blue emission layer 173, respectively. The first to third hole transport layers 135, 157, and 175 may be configured to transport holes to the emission layers 133, 153-155, and 173, respectively.

The first stack S1 adjacent to the cathode 120 may further include an electron injection layer 125 disposed between the cathode 120 and the first electron transport layer 130, the electron injection layer 125 being configured to inject electrons from the cathode 120 into the intermediate functional layer OS. The third stack S3 adjacent to the anode 200 may further include a hole injection layer 177 disposed between the third hole transport layer 175 and the anode 200, the hole injection layer 177 being configured to inject holes from the anode 200 into the intermediate functional layer OS.

The first and second charge generation layers 140 and 160 provided between the stacks may respectively include p-type charge generation layers 140a and 160a configured to generate holes and to transport the holes to stacks adjacent thereto and n-type charge generation layers 140b and 160b configured to generate electrons and to transport the electrons to stacks adjacent thereto.

The white light emitting device ED according to an example embodiment of the present disclosure may include the optical compensation layer 110 abutting the first surface SF1 of the cathode 120 that faces the substrate 100, and this can advantageously reduce the thickness of the intermediate functional layer OS and the thickness of the cathode 120. In particular, the optical compensation layer 110 abuts the first surface SF1 of the cathode 120, which is opposite the second surface SF2 that faces the intermediate functional layer OS, and this can advantageously adjust a cavity. The optical compensation layer 110 may reduce the thickness of the intermediate functional layer OS, particularly the thickness of the first electron transport layer 130, the first blue emission layer 133 may be adjacent to the second surface SF2 of the cathode 120, and a resonance thickness required for the intermediate functional layer OS of the white light emitting device ED may be reduced, whereby the driving voltage can be greatly and advantageously reduced.

In one or more aspects, the reason that a driving voltage of the white light emitting device ED according to an embodiment of the present invention is reduced is that a configuration of the present disclosure can reduce an entire thickness of the intermediate functional layer OS, especially, to reduce a thickness of the electron transport layer, which has a relatively low mobility than any other organic layers of the intermediate functional layer OS.

In one or more examples, in a light emitting device in which light is emitted only by resonance between opposite electrodes (anode-cathode or cathode-anode), the thickness of a common layer adjacent to the lower electrode (a cathode or an anode) is increased in order to adjust the light emitting position of an emission layer located in the lowest stack when a plurality of stacks is provided between both electrodes. A thick common layer may cause an increase in driving voltage of the light emitting device. In a normal light emitting device (e.g., a non-inverted light emitting device), a thick common layer adjacent to the lower electrode may be represented as a hole transport layer. In an inverted light emitting device, a thick common layer adjacent to the lower electrode may be represented as an electron transport layer. Furthermore, since most material for the electron transport layer has a lower mobility than other transport materials provided in the intermediate functional layer OS, there is a problem in that a driving voltage is severely increased due to an increase in thickness of the electron transport layer adjacent to the cathode in the inverted light emitting device having the thick electron transport layer than the normal light emitting device having the hole transport layer. The white light emitting device according to the present invention may solve this problem, since the optical compensation layer 110 abutting the cathode 120 can adjust the cavity order. In one or more aspects, a cavity may refer to a region (e.g., the intermediate functional layer OS) between the cathode 120 and the anode 200. In one or more aspects, a cavity order may relate to the order in the cavity (e.g., the thicknesses of the layers within the cavity).

In addition, in the white light emitting device ED according to the present invention, the thickness of the intermediate functional layer OS between the cathode 120 and the anode 200 may be reduced, and the cavity order may be reduced, which can prevent the deterioration in characteristics of a viewing angle.

If a light emitting device is controlled by only resonance in the intermediate functional layer OS between the cathode and the anode (or the anode and the cathode), the light emitting device should satisfy a constructive interference condition. Further, the constructive interference condition is relative to an optical condition of 2 nd =mλ (“n” is an average refractive index, “d” is a thickness of the intermediate functional layer OS, “λ” is a wavelength of the emitted light and ‘m’ is an integer). In this case, the cavity order is proportional to the integer “m” of the optical condition. Thus, in the light emitting device which is controlled by only resonance in the intermediate functional layer OS between the cathode and the anode (or the anode and the cathode), the cavity order increases in proportion to a total thickness of the intermediate functional layer OS. In order to generate a micro-cavity effect, the intermediate functional layer OS should satisfy the optical condition based on constructive interference by only resonance between the cathode and the anode (or the anode and the cathode).

On the contrary, in the white light emitting device ED according to the embodiment of the present disclosure, not only the intermediate functional layer OS but also the optical compensational layer 110 which is in contact with the cathode 120 compensates the cavity of the intermediate functional layer OS. So the thickness of the intermediate functional layer OS of the white light emitting device ED according to the embodiment of the present disclosure can be reduced than thickness of the intermediate functional layer of the white light emitting device which is controlled by only resonance in the intermediate functional layer. Furthermore, the reduced thickness of the intermediate functional layer OS makes it possible to reduce the cavity order and a driving voltage of the white light emitting device ED.

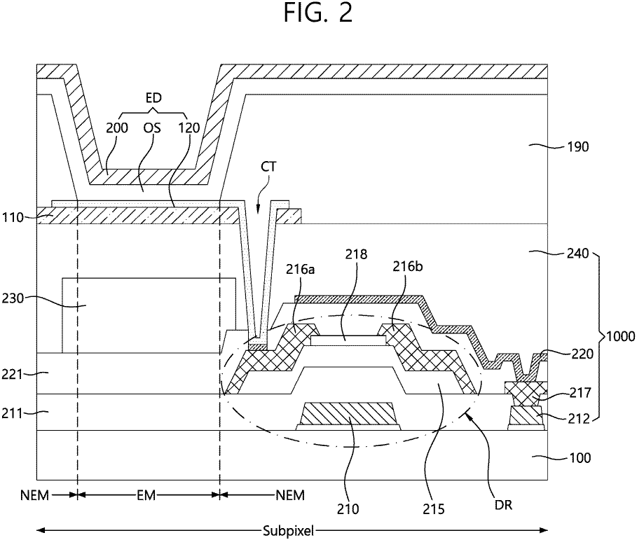

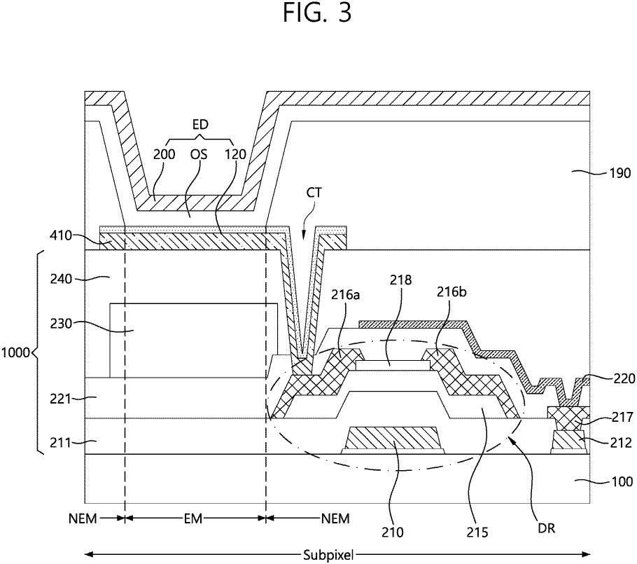

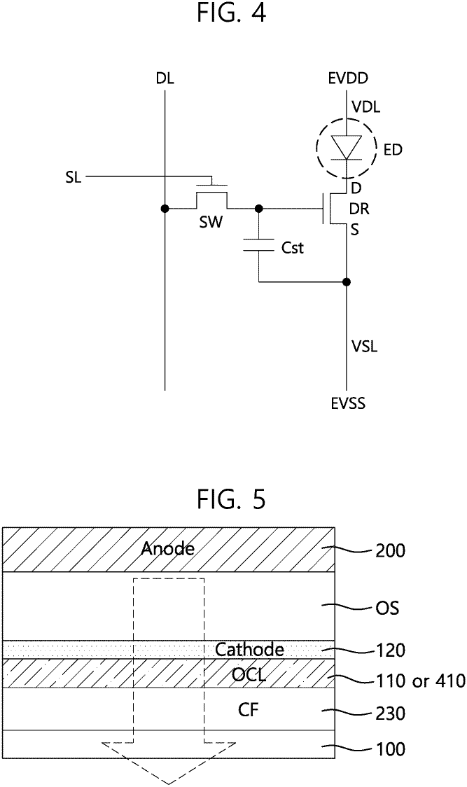

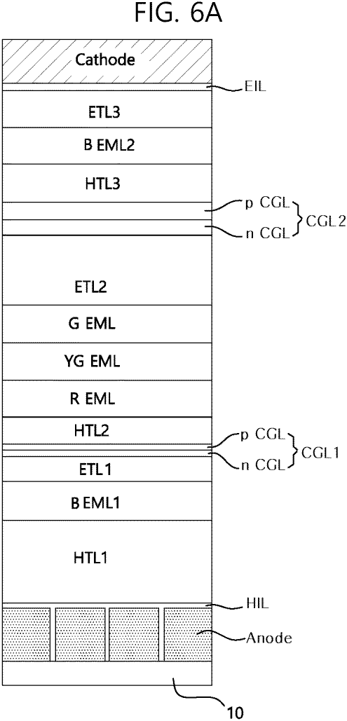

FIG. 2 and FIG. 3 are sectional views showing one subpixel of display devices according to various example embodiments of the present disclosure, FIG. 4 is an example of a circuit diagram of one subpixel of a display device having the white light emitting device of FIG. 1, and FIG. 5 is a sectional view schematically showing an optical functional layer of the display device according to an example embodiment of the present disclosure.

As shown in FIG. 2 and FIG. 3, the display device according to various example embodiments of the present disclosure may have a plurality of subpixels. Each of FIG. 2 and FIG. 3 illustrates one subpixel of the plurality of subpixels. In one or more examples, each subpixel may have the same or a similar configuration as that shown in FIG. 2 or FIG. 3. Each subpixel may have an emission portion EM and a non-emission portion NEM provided around the emission portion. The display device may include a substrate 100, a subpixel driving circuit provided in the non-emission portion NEM of each subpixel on the substrate (e.g., the components shown in FIG. 4 excluding an ED), a planarization layer 240 configured to cover the subpixel driving circuit, an optical compensation layer 110 or 410 provided on the planarization layer so as to correspond to (or be associated with) the emission portion EM of each subpixel, and a white light emitting device ED provided in each subpixel, the white light emitting device abutting the optical compensation layer 110 or 410, the white light emitting device ED having the cathode 120, the anode 200 and the intermediate functional layer OS therebetween, shown in FIG. 1. In one or more example embodiments of the present disclosure, a light emitting device, or a white light emitting device, may be an organic LED; however, the present disclosure is not limited thereto, and in one or more other examples, a light emitting device, or a white light emitting device, may be an inorganic LED.

In one or more examples, the substrate 100 may extend throughout the plurality of subpixels (see, e.g., FIG. 13).

It is noted that each of FIG. 2 and FIG. 3 illustrates that the white light emitting device ED includes the cathode 120, the anode 200 and the intermediate functional layer OS but does not show the other components in the emission portion EM (e.g., the layers/elements 110, 230, 221, 211 and 100). However, in one or more examples (see, e.g., FIG. 1), it may be described that the white light emitting device ED includes not only the cathode 120, the anode 200 and the intermediate functional layer OS but also some or all of the other components in the emission portion EM.

As shown in FIG. 4, the subpixel driving circuit may include a switching transistor SW provided at the intersection between a scan line SL and a data line DL, a driving transistor DR connected to the switching transistor SW and the cathode 120 (see FIG. 2 or FIG. 3) of the white light emitting device ED, and a storage capacitor Cst connected between a connection node of the switching transistor SW and the driving transistor DR and a source electrode S of the driving transistor DR. The anode of the white light emitting device ED may be connected to a driving supply voltage line VDL to receive a driving supply voltage EVDD, and the source electrode S of the driving transistor DR may be connected to a ground supply voltage line VSL to receive a ground supply voltage EVSS. A gate electrode of the switching transistor SW may be connected to the scan line SL to receive a scan signal, and the driving transistor DR may be connected to the switching transistor SW and may be turned on according to a signal transmitted from the switching transistor SW.

The display device according to an example embodiment of the present disclosure includes an inverted light emitting device. The anode may be directly connected to the driving supply voltage line VDL, and the cathode may be connected to a node of a drain electrode D of the driving transistor DR. When the driving transistor DR is turned on, therefore, the driving supply voltage EVDD may be applied to the driving supply voltage line VDL, a current path may be immediately formed in the white light emitting device ED, whereby light may be emitted, and therefore the operation of the white light emitting device ED can be performed without deterioration of the driving transistor DR. Consequently, it is not necessary to dispose a separate sense transistor for initialization or a reference voltage line to which initialization voltage is applied. This advantageously simplifies the construction of the subpixel driving circuit, and the simplified subpixel driving circuit may be disposed in a bottom emission structure in which light is emitted through the substrate 100, which can advantageously maximize the emission portion.

In the display device according to an example embodiment of the present disclosure, each of the switching transistor SW and the driving transistor DR included in the subpixel is an N-type transistor as an example. However, the present disclosure is not limited thereto. One of the switching transistor SW and the driving transistor DR transistors in the sub-pixel may be an N-type transistor, and the other may be a P-type transistor. In some other cases, the switching transistor SW and the driving transistor DR may be P-type transistors.

In the subpixel, when a data signal and a scan signal are supplied from a data driving portion (not shown) and a scan driving portion (not shown) through the data line and the scan line, whereby the switching transistor is switched, a current path may be formed in the driving supply voltage line VDL, the white light emitting device ED, the driving transistor DR, and the ground supply voltage line VSL. This current path causes the white light emitting device ED to emit light.

As an example, as shown in FIG. 2, the driving transistor DR of the subpixel driving circuit includes a gate electrode 210 on the substrate 100, a semiconductor layer 215, a gate dielectric film 211 interposed between the semiconductor layer 215 and the gate electrode 210, and a drain electrode 216a and a source electrode 216b provided at opposite sides of the semiconductor layer 215 so as to be spaced apart from each other.

The gate electrode 210 may include metal, such as one or more of aluminum (Al), chromium (Cr), copper (Cu), titanium (Ti), molybdenum (Mo), tungsten (W), and an alloy of any of the foregoing. In addition, as shown, the gate electrode 210 may be formed so as to have a dual-layered structure, wherein at least one of the stacked layers may be used as a barrier layer configured to prevent the semiconductor layer 215 from being affected by impurities or moisture introduced from a lower side of the substrate 100. In other examples, the gate electrode 210 may be formed so as to have a single-layered structure or a multilayered structure including three or more layers.

The drain electrode 216a and the source electrode 216b may be made of metal on the same layer. Each of the drain electrode 216a and the source electrode 216b may also be formed so as to have a single-layered structure. However, the present disclosure is not limited thereto, and each of the drain electrode Y and the source electrode 216b may be formed so as to have a multilayered structure.

The semiconductor layer 215 may be any one of an oxide semiconductor layer, polysilicon, and amorphous silicon, or may be formed by stacking two or more different layers. When the semiconductor layer 215 includes an oxide semiconductor layer and polysilicon, the semiconductor layer 215 may be formed using a crystallization process. The semiconductor layer 215 may further include an etching prevention film 218 at a channel region in order to prevent over-etching. Depending on the circumstances, the etching prevention film 218 may be omitted.

Meanwhile, in the same process as forming the driving transistor DR, the scan line SL, the data line DL, the driving supply voltage line VDL, the ground supply voltage line VSL, the switching transistor SW, and the storage capacitor Cst, described with reference to FIG. 4, may also be formed. In addition, the ground supply voltage line VSL may be connected to a first connection electrode 212 on the same layer as the gate electrode 210 of FIG. 2 or FIG. 3 and a second connection electrode 217 on the same layer as the drain electrode 216a and the source electrode 216b, where a connection line pattern 220 may be provided in the non-emission portion NEM of the subpixel on the substrate.

The switching transistor SW and the driving transistor DR may be protected by a passivation film 221, and the connection line pattern 220 may be provided on the passivation film 221.

A color conversion layer 230 is provided on the passivation film 221 so as to correspond to (or be associated with) at least the emission portion EM, and the planarization layer 240 is provided so as to cover the color conversion layer 230, the passivation film 221, and the connection line pattern 220. The planarization layer 240 may be made of an organic material that can be plane such that the white light emitting device ED formed thereon has a uniform surface.

The construction including the subpixel driving circuit, such as the driving transistor DR, the dielectric layers 211, 221, and 240, and the color conversion layer 230, formed on the substrate 100, may be referred to as an array 1000. An array 1000 may be sometimes referred to as an array substrate 1000.

In the display device according to an example embodiment of the present disclosure, the optical compensation layer 110 or 410 is provided on the planarization layer 240 so as to correspond to (or be associated with) at least the emission portion EM. The optical compensation layer 110 or 410 may be formed so as to correspond to (or be associated with) only the emission portion EM, or may be formed so as to correspond to (or be associated with) the entirety of the emission portion EM and a part or the entirety of the non-emission portion NEM around the emission portion EM.

A contact hole CT may be provided in the optical compensation layer 110 or 410 and the planarization layer 240 in order to expose a part of the drain electrode 216a. The cathode 120 may be connected to the drain electrode 216a through the contact hole CT, and may be formed on the planarization layer 240. For an example, as shown in FIG. 2, the contact hole CT is a common hole continuously formed in the planarization layer 240 and the optical compensation layer 110. When the optical compensation layer 110 is located only in the emission portion EM, the contact hole CT and the optical compensation layer 110 located in the non-emission portion NEM do not overlap each other. In this case, the contact hole CT may be provided in the planarization layer 240.

A bank 190 may be provided on the array substrate 1000 in order to expose the emission portion EM of each subpixel. The bank 190 may be formed on the cathode 120 located in a part of the non-emission portion NEM so as to overlap the cathode 120.

In the display device illustrated in FIG. 2, the optical compensation layer 110 is a transparent insulating layer. In this case, the optical compensation layer 110 compensates a cavity without causing other electrical influences from an outside of the white light emitting device ED. For an electrical connection between the cathode 120 and the drain electrode 216a, the optical compensation layer 110 may be removed from a contact hole CT. As shown in FIG. 2, in order to reduce a connection resistance between the cathode 120 and the drain electrode 216a, a metal, which is the same layer as a connection line pattern 220, is further provided between the cathode 120 and the drain electrode 216a. The optical compensation layer 110 has a refractive index greater than a refractive index of the cathode 120, so that optical loss is prevented at an interface between the cathode 120 and the optical compensation layer 110, and a light output efficiency is increased when a light generated at the white light emitting device ED is transmitted from the cathode 120 through the optical compensation layer to a lower side of the substrate 100.

In FIG. 3, the display device includes the optical compensation layer 410 of a transparent electrode different from the cathode 120. The optical compensation layer 410 is under the cathode 120 and in contact with the cathode 120. For example, the cathode 120 may be indium tin oxide (ITO), and the optical compensation layer 410 may be indium zinc oxide (IZO). However, the cathode 120 and the optical compensation layer 410 are not limited thereto. If the optical compensation layer 410 has a higher refractive index than that of the cathode 120, the optical compensation layer 410 and the cathode can be changed to another type of transparent electrode. In some case, even if the cathode 120 and the optical compensation layer 410 include the same metal component, the refractive indices of the cathode 120 and the optical compensation layer 410 may be varied by changing their ratio.

The optical compensation layer 410 has a refractive index greater than a refractive index of the cathode 120, so that optical loss is prevented at an interface between the cathode 120 and the optical compensation layer 410, and a light output efficiency is increased when a light generated at the white light emitting device ED is transmitted from the cathode 120 through the optical compensation layer to a lower side of the substrate 100.

In the display devices of FIG. 2 and FIG. 3, a refractive index difference between the optical compensation layer 110 and 410 and the cathode 120 may be 0.1 or more, and 0.4 or less. Furthermore, if the optical compensation layer 110 or 410 has the refractive index similar to or greater than an average index of the intermediate functional layer OS, it may be effective for the intermediate functional layer to compensate for the optical cavity.

In the display device of FIG. 3, since the optical compensation layer 410 is made of the transparent electrode and has conductivity (or is conductive), the optical compensation layer 410 and the cathode 120 can be formed at a same processing step. In this case, as shown in FIG. 3, the optical compensation layer 410 and the cathode 120 have the same width, and the drain electrode 216a of the driving transistor DR can be directly connected to the optical compensation layer 410. The cathode 120 is electrically connected to the drain electrode 216a through the optical compensation layer 410, and receives an electrical signal from the driving transistor DR. Also, as shown in FIG. 3, the optical compensation layer 410 may electrically connect the driving transistor DR to the cathode 120. The cathode 120 and the optical compensation layer 410 are doubly connected with the drain electrode 216a at the contact hole CT, so that an electrical resistance can be reduced or prevented at the contact hole between the drain electrode 216a and the cathode 120.

In a display device according to another example embodiment, the optical compensation layer 410 and the cathode 120 of FIG. 3 may be modified to have different widths.

The display device of FIG. 3 has the same or substantially the same functional characteristics as the display device of FIG. 2 in compensating the cavity of the intermediate functional layer OS with the optical compensation layer 410. Furthermore, an entire thickness of the intermediate functional layer OS in the white light emitting device ED is reduced by providing the optical compensation layer 410 under the cathode 120, so that a driving voltage can be reduced and the cavity order can be reduced.

As shown in FIGS. 1 to 5, in the display device according to an example embodiment of the present disclosure, when a voltage is applied to each of the cathode 120 and the anode 200, a driving current may be generated therebetween. When the anode 200 is a reflective electrode and the cathode 120 is a transparent electrode and when light is generated in the intermediate functional layer OS, light resonated in the intermediate functional layer OS between both electrodes 200 and 120 may finally pass through the cathode 120, the light that has passed through the cathode 120 may pass through the optical compensation layer 110 or 410 and the color conversion layer 230, and light having the wavelength selectively transmitted by the color conversion layer 230 may be transmitted through the substrate 100.

The anode 200 may be formed of a reflective electrode. The anode 200 may include at least one of aluminum, silver, gold, and magnesium or may be an aluminum alloy, a silver alloy, a gold alloy and magnesium alloy.

Meanwhile, in the display device including the white light emitting device ED according to an example embodiment of the present disclosure, the optical compensation layer 110 or 410 may be a transparent dielectric film or a transparent electrode. In one or more aspects, the reason for this is that it is necessary for the optical compensation layer 110 or 410 to compensate for the cavity without causing other electrical influences outside the white light emitting device ED. In addition, the optical compensation layer 110 may be formed so as to have a thickness of 1000 Å to 3000 Å in order to compensate for the optical cavity in all of the red, green, blue, and white subpixels provided on the substrate 100. More preferably, the optical compensation layer 110 or 410 has a thickness of 1100 Å to 2400 Å.

The cathode 120 may have a thickness of 1000 Å or less, which is less than the thickness of the optical compensation layer 110 or 410, such that light from emission layers provided between the cathode 120 and the anode 200 is transmitted to the outside through the cathode 120 and transparency of the cathode 120 is improved. More preferably, the cathode 120 has a thickness of 100 Å to 700 Å.

The optical compensation layer 110 or 410 may be made of a transparent dielectric film or a transparent electrode having a refractive index equal to or greater than the average refractive index of the intermediate functional layer OS in order to improve a light emission effect of light emitted from the white light emitting device ED without causing internal total reflection.

The optical compensation layer 110 or 410 may have a refractive index greater than the refractive index of the cathode 120. The refractive index of the optical compensation layer 110 or 410 may be 0.1 to 0.4 greater than that of the cathode 120 (e.g., may be greater than that of the cathode 120 by 0.1 to 0.4). The optical compensation layer 110 or 410 of the display device may emit light to the outside in an advancing direction of the light that has passed through the cathode 120 without substantial reflection by the first surface SF1 of the cathode 120. In addition, the entire optical compensation layer 110 of the display device in FIG. 2 or a portion thereof may have a silicon nitride film, which is a material having high transmittance without internal absorption of light. In the display device of FIG. 3, the optical compensation layer 410 may have a high transmittance without internal absorption of light and may include a transparent electrode having a refractive index greater than that of the cathode 120. For an example, the optical compensation layer 410 may be (or may include) indium zinc oxide (IZO). In this case, the cathode 120 may be (or may include) indium tin oxide (ITO).

Depending on the circumstances, if the material of the optical compensation layer 110 or 410 has low light absorbance, has a refractive index equal to or greater than the average refractive index of the intermediate functional layer OS, and has substantially no reflectance at the surface abutting the cathode 120, a material of the optical compensation layer 110 or 410 may be used as an alternative.

Hereinafter, a reason for having the optical compensation layer in each of the white light emitting device and the display device according to an example embodiment of the present disclosure and the effect of the optical compensation layer at a specific thickness thereof will be described with reference to experimental examples.

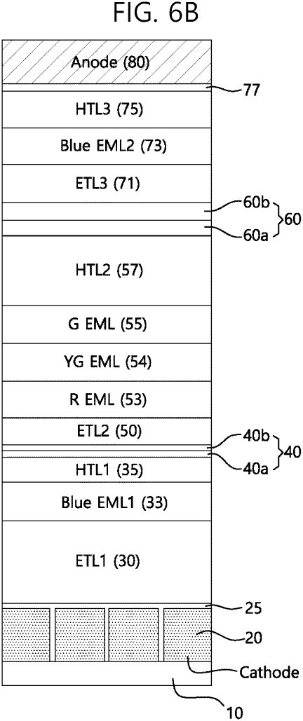

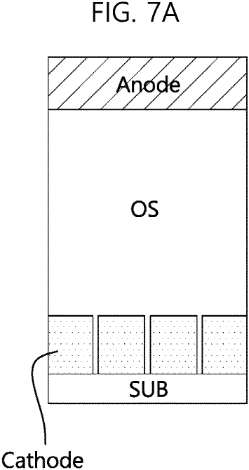

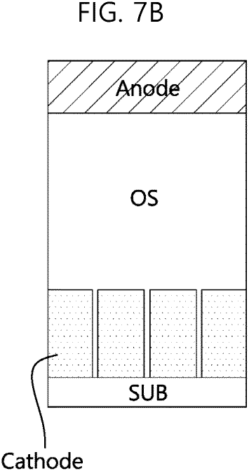

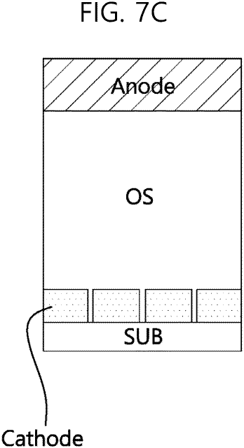

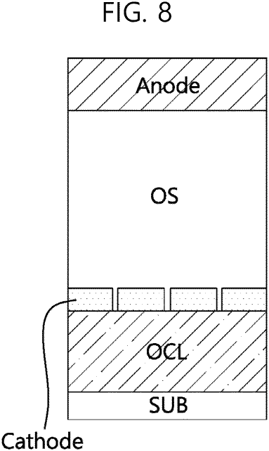

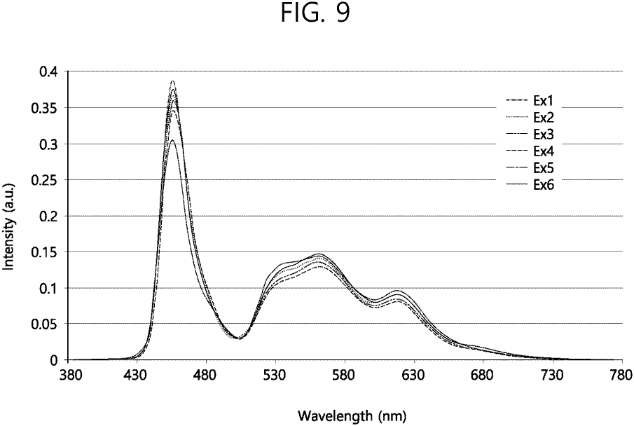

FIGS. 6A and 6B are examples of sectional views showing white light emitting devices used in a first experimental example (Ex1) and a second experimental example (Ex2), and FIGS. 7A to 7C are examples of sectional views showing third to fifth experimental examples. FIG. 8 is an example of sectional view showing a sixth experimental example. In addition, FIG. 9 is an example of a graph showing white spectra of the first to sixth experimental examples.

FIG. 8A shows a white light emitting device having a normal (or non-inverted) structure, which is the inverse of the structure of FIG. 1, according to a first experimental example (Ex1). In the white light emitting device according to the first experimental example, an anode Anode, a hole injection layer HIL, a first hole transport layer HTL1, a first blue emission layer B EML1, a first electron transport layer ETL1, a first charge generation layer CGL1, a second hole transport layer HTL2, a red emission layer R EML, a yellowish green emission layer YG EML, a green emission layer G EML, a second electron transport layer ETL2, a second charge generation layer CGL2, a third hole transport layer HTL3, a second blue emission layer B EML2, a third electron transport layer ETL3, an electron injection layer EIL, and a cathode Cathode are sequentially formed on a substrate 10. In the normal white light emitting device according to the first experimental example (Ex1), each of the first and second charge generation layers CGL1 and CGL2 may have a structure in which a p-type charge generation layer p CGL is stacked on an n-type charge generation layer n CGL. The normal white light emitting device according to the first experimental example (Ex1) emits light through the substrate 10.

In the first experimental example (Ex1), the anode located at a lower side is ITO, and the cathode located at an upper side is aluminum (Al).

In the second to sixth experimental examples (Ex2 to Ex6), the cathode located at a lower side is ITO, and the anode located at an upper side is aluminum (Al).

FIG. 6B shows an inverted white light emitting device according to a second experimental example (Ex2), which has the same intermediate functional layer as the intermediate functional layer OS described with reference to FIG. 1. In the white light emitting device according to the second experimental example (Ex2), light is emitted only by resonance between a cathode and an anode, and light is emitted through a substrate 10 under the cathode.

In the white light emitting device according to the second experimental example (Ex2), a cathode Cathode (20), an electron injection layer 25, a first electron transport layer ETL1 (30), a first blue emission layer B EML1 (33), a first hole transport layer HTL1 (35), a first charge generation layer 40, a second electron transport layer ETL2 (50), a red emission layer R EML (53), a yellowish green emission layer YG EML (54), a green emission layer G EML (55), a second hole transport layer HTL2 (57), a second charge generation layer 60, a third electron transport layer ETL3 (71), a second blue emission layer B EML2 (73), a third hole transport layer HTL3 (75), a hole injection layer 77, and an anode Anode (80) are sequentially formed on the substrate 10. In the first and second charge generation layer 40 and 60, n-type charge generation layers 40b and 60b are stacked on p-type charge generation layers 40a and 60a, respectively. The inverted white light emitting device according to the second experimental example emits light through the substrate 10.

Each of the white light emitting devices according to the third to fifth experimental examples (Ex3, Ex4, and Ex5) shown in FIGS. 7A to 7C has the same inverted structure as shown in FIG. 6B. However, there is a difference therebetween in terms of the total thickness of the intermediate functional layer OS and the thickness of the cathode Cathode abutting the substrate SUB.

As shown in FIG. 8, the inverted white light emitting device according to the sixth experimental example (Ex6) is configured such that the intermediate functional layer OS shown in FIG. 1 is provided between a cathode Cathode and an anode Anode and such that an optical compensation layer OCL is provided between a substrate SUB and the cathode Cathode. A silicon nitride film is used as the optical compensation layer OCL of the sixth experimental example (Ex6).

The first experimental example (Ex1) and the second experimental example (Ex2) are different from each other in terms of whether the white light emitting device has a normal structure or an inverted structure. In the first experimental example (Ex1), the lowest electrode is the anode, and a transparent electrode made of ITO is used as the anode. In the second experimental example (Ex2), the lowest electrode is the cathode, and a transparent electrode made of ITO is used as the cathode. In each of the first and second experimental examples, the transparent electrode made of ITO, which is the lowest electrode, has a thickness of 1200 Å.

The white light emitting device of the first experimental example (Ex1), the anode is connected to the driving transistor and the cathode is connected to a ground supply voltage line VSL. In addition, the driving transistor DR is connected between a driving supply voltage line VDL and the anode of the white light emitting device ED. In this case, a turn-on of the white light emitting device ED is affected by the driving characteristics of the driving transistor DR. Therefore, the white light emitting device ED of the normal structure may further have a sensor transistor at a connection node between the white light emitting device ED and the driving transistor DR to detect a change of a threshold voltage based on deterioration of the driving transistor DR. Consequently, a complex pixel circuit in a sub-pixel may be required in the normal structure compared to the white light emitting device having an inverted structure, and it may lower the aperture ratio of the display device.

On the other hand, the white light emitting devices ED according to the second experimental example (Ex2) to the sixth experimental example (Ex6) have the inverted structure, as shown in FIG. 4. The anode is directly connected to the driving supply voltage line VDL, and the cathode is connected to a node of a drain electrode D of the driving transistor DR. Therefore, when the driving transistor DR is turned on, the driving supply voltage EVDD is applied to the driving supply voltage line VDL, a current path is immediately formed in the white light emitting device ED, whereby light may be emitted. Thus, the operation of the white light emitting device ED is possible without deterioration of the driving transistor DR. Consequently, it is not necessary to dispose a separate sense transistor for initialization or a reference voltage line to which initialization voltage is applied, whereby it is possible to simplify construction of the subpixel driving circuit, and the simplified subpixel driving circuit may be disposed in a bottom emission structure in which light is emitted through the substrate 100, whereby it is possible to maximize the emission portion.

The thickness of the cathode and the thickness of the first electron transport layer abutting the cathode of each of the inverted white light emitting devices according to the second experimental example (Ex2) to the sixth experimental example (Ex6) are shown in Table 1. Effects of the second experimental example (Ex2) to the sixth experimental example (Ex6) are shown in Table 1. In the second experimental example (Ex2), the thickness of the first electron transport layer is 910 Å, and the thickness of the cathode is 1200 Å. In the third experimental example (Ex3), the thickness of the first electron transport layer is 500 Å, and the thickness of the cathode is 1658 Å. In the third experimental example (Ex3), the thickness of the first electron transport layer ETL1 is decreased and the thickness of the cathode is increased, compared to the second experimental example (Ex2). In the fourth experimental example (Ex4), the thickness of the first electron transport layer ETL1 is 100 Å, and the thickness of the cathode (ITO) is 2090 Å. In order to reduce the driving voltage, the thickness of the first electron transport layer ETL1 is decreased and the thickness of the cathode (ITO) is increased, compared to the third experimental example (Ex3). In the fifth experimental example (Ex5), the thickness of the first electron transport layer ETL1 is 100 Å, and the thickness of the cathode (ITO) is 440 Å. This experimental example is provided to determine an optical change when the thickness of the cathode is reduced, compared to the fourth experimental example (Ex4).

The white light emitting device according to the sixth experimental example (Ex6) is different from the white light emitting device according to the fifth experimental example (Ex5) in that the thickness of the cathode is reduced and the optical compensation layer OCL is further included. The thickness of the first electron transport layer is 100 Å, the thickness of the cathode is 330 Å, and the thickness of the optical compensation layer OCL is 1580 Å.

Meanwhile, in the first experimental example (Ex1), a thickness of the intermediate functional layer OS between the anode Anode and the cathode Cathode is 3470 Å, and in the second experimental example (Ex2), a thickness of the intermediate functional layer OS between the cathode Cathode and the anode Anode is 4280 Å. The second experimental example (Ex2) has an increased cavity order by increasing the thickness of the first electron transport layer adjacent to the cathode, compared to the first experimental example (Ex1). In the third experimental example (Ex3), a thickness of the intermediate functional layer OS between the cathode Cathode and the anode Anode is 3870 Å by reducing the thickness of the first electron transport layer adjacent to the cathode, compared to the second experimental example (Ex2). In the fourth to sixth experimental examples (Ex4 to Ex6), the total thickness of the intermediate functional layer OS is 3470 Å. The reason for this is that, in the fourth to sixth experimental examples (Ex4 to Ex6), the thickness of the first electron transport layer ETL1 is reduced by 400 Å, compared to the third experimental example (Ex3).

In addition, in Table 1, a driving voltage, a red efficiency (R efficiency), a green efficiency (G efficiency), a blue efficiency (B efficiency), and a white efficiency (W efficiency) of each of the experimental examples excluding the first experimental example (Ex1) are provided as relative values in relation to the first experimental example (Ex1).

TABLE 1

| | Structure (Thickness)[Å] | | | Driving voltage (vs Ex1) [V] | R efficiency (%) | G efficiency (%) | B efficiency (%) | W efficiency (%) | Deviation of viewing angle (Δu′v′) |
|---|---|---|---|---|---|---|---|---|---|
| | ETL1 | ITO [Anode/ Cathode] | OCL | | | | | | |
| Ex1 | 100 | 1200 [Anode] | - | 0 | 100 | 100 | 100 | 100 | 0.0226 |
| Ex2 | 910 | 1200 [Cathode] | - | +2.2 | 107 | 98 | 99 | 101 | 0.0253 |
| Ex3 | 500 | 1658 [Cathode] | - | 0 | 100 | 94 | 99 | 97 | 0.0247 |
| Ex4 | 100 | 2090 [Cathode] | - | -1.1 | 96 | 90 | 96 | 93 | 0.0242 |
| Ex5 | 100 | 440 [Cathode] | - | -1.1 | 114 | 105 | 90 | 105 | 0.0252 |
| Ex6 | 100 | 330 [Cathode] | 1580 | -1.1 | 109 | 102 | 101 | 104 | 0.0198 |

As shown in Table 1, in the second experimental example (Ex2), in which the structure of the first experimental example (Ex1) is inverted, the thickness of the first electron transport layer abutting the cathode is increased, whereby the driving voltage is increased due to the increased thickness of the first electron transport layer and the low mobility of the first electron transport layer, compared to the first experimental example (Ex1). When the thickness of the cathode is increased, as in the third experimental example (Ex3), in order to solve the problem in that the driving voltage of the inverted white light emitting device according to the second experimental example (Ex2) is increased, similar driving voltage characteristics as in the first experimental example (Ex1) are achieved, but the green efficiency, blue efficiency, and white efficiency are lowered. In addition, it can be seen as shown in Table 1 that the deviation of the viewing angle when the white light emitting device is viewed at an angle of 45 degrees compared to when the white light emitting device is viewed in front is increased, compared to the first experimental example (Ex1).

Meanwhile, it can be seen that, in the fourth to sixth experimental examples (Ex4 to Ex6), in which the thickness of the first electron transport layer is reduced to ⅕ of the thickness of the first electron transport layer in the third experimental example (Ex3), the driving voltage is lower by 1.1 V from that of the first experimental example (Ex1), whereby the driving voltage is reduced. However, it can be seen that, in the fourth experimental example (Ex4) and the fifth experimental example (Ex5), the deviation of the viewing angle of the white light emitting device is greater than that of the first experimental example (Ex1). In particular, it can be seen that, in the fourth experimental example (Ex4), the red, green, blue, and white efficiencies are reduced, whereby the color efficiency is reduced. In contrast, it can be seen that, in the fifth experimental example (Ex5), the thickness of the cathode is less than that of the fourth experimental example (Ex4), whereby the red, green, and white efficiencies are increased, but the blue efficiency is greatly reduced, and the deviation of the viewing angle is more greatly increased. The reason for this is that the thin cathode abuts the first electron transport layer ETL1, the first blue emission layer is within a short distance under the cathode, and the white light emitting device emits light through only resonance between the cathode and the anode, whereby the blue efficiency is not sufficiently secured.

In contrast, in the sixth experimental example (Ex6), the optical compensation layer of the transparent dielectric film such as SiNx is provided under the cathode, whereby the cavity of the light that has passed through the cathode is compensated for by the optical compensation layer thereunder even though the thin cathode and the thin first electron transport layer are provided, and therefore the light is emitted to the outside with a high emission efficiency. Consequently, it can be seen that, in the sixth experimental example (Ex6), the red, green, blue, and white efficiencies are higher than in the normal white light emitting device according to the first experimental example (Ex1) as well as the inverted white light emitting device according to the second experimental example (Ex2). Furthermore, in the sixth experimental example (Ex6), as shown in Table 1, the deviation of the viewing angle is 0.0198, which is the smallest in all of the experimental examples, and therefore it can be expected that the abnormal visible amount due to a change in the viewing angle is the smallest. This means that, in the sixth experimental example (Ex6), a viewer can view an image having higher quality than in the other experimental examples.

The first experimental example (Ex1) is a normal (non-inverted) white light emitting device and the second experimental example (Ex2) to sixth experimental example (Ex6) are inverted white light emitting devices. Among inverted white light emitting devices, only the sixth experimental example (Ex6) includes the optical compensation layer OCL, and the second experimental example (Ex2), third experimental example (Ex3), the four experimental example (Ex4) and fifth experimental example (Ex5) have differences in the thickness of the cathodes Cathode and the first electron transport layers ETL1.

Hereinafter, with reference to Table 2, an effect of a seventh experimental example (Ex7) in which the optical compensation layer is a transparent electrode such as IZO different from the cathode will be described.

In the following experiments according to Table 2, the lower electrode (anode or cathode) is formed of ITO and the upper electrode (cathode or anode) is formed of Al.

A first experimental modification example (Ex1a) is based on the normal structure as shown in FIG. 6A; thus, the lower electrode is an anode formed of ITO. A second experimental modification example (Ex2a) is based on the inverted structure as shown in FIG. 6B; thus, the lower electrode is a cathode formed of ITO. The anode of the first experimental modification example (Ex1a) and the cathode of the second experimental modification example (Ex2a) have thicknesses of 1100 Å, respectively.

The seventh experimental example (Ex7) follows the configuration of the white light emitting device of FIG. 1 described above. The seventh experimental example (Ex7) is different from the above sixth experimental example (Ex6) in that the material of the optical compensation layer is a transparent electrode of indium zinc oxide IZO, and the other features are the same as those of the above sixth experimental example (Ex6). The third experimental example (Ex3) Of Table 2 is the same as the third experimental example (Ex3) of Table 1.

In the seventh experimental example (Ex7), a transparent electrode of IZO as the optical compensation layer OCL is formed with a thickness of 1300 Å on the substrate. Subsequently, a transparent electrode of ITO as the cathode 120 is formed on the optical compensation layer OCL with a thickness of 550 Å. Thereafter, a first electron transport layer ETL1 is formed on the cathode, with a thickness of 100 Å. In the seventh experimental example (Ex7), an entire thickness of the intermediate functional layer OS is 3470 Å as in the sixth experimental example (Ex6).

TABLE 2

| | Structure (Thickness) [Å] | | | Driving voltage (vs Ex1a)[V] | R Efficiency (%) | G Efficiency (%) | B Efficiency (%) | W Efficiency (%) |
|---|---|---|---|---|---|---|---|---|
| | ETL1 | ITO [Anode/ Cathode] | OCL | | | | | |
| Ex1a | 100 | 1100 [Anode] | - | 0 | 100 | 100 | 100 | 100 |
| Ex2a | 910 | 1100 [Cathode] | - | +2.2 | 107 | 98 | 99 | 101 |
| Ex3 | 500 | 1658 [Cathode] | - | 0 | 100 | 94 | 99 | 97 |
| Ex7 | 100 | 550 [Cathode] | 1300 | -1.1 | 99 | 98 | 109 | 116 |

As shown in Table 2, the white light emitting device ED of the seventh experimental example (Ex7) has an advantage in that a driving voltage is reduced by 1.1 V compared to the white light emitting device of the first experimental modification example (Ex1a). This may be an effect obtained by reducing an electrical resistance in the electrical connection between the cathode and the optical compensation layer. Furthermore, the seventh experimental example (Ex7) represents red and green efficiencies similar to those of the first experimental modification example (Ex1a) and an outstanding blue efficiency which is 109% of the blue efficiency of the first experimental modification example (Ex1a). In addition, the seventh experimental example (Ex7) has a white efficiency which is 116% of the white efficiency of the first experimental modification example (Ex1a), by stacking the cathode and the optical compensation layer without an internal light loss therebetween. The white efficiency may be measured at a white transmissive part that does not include any color filters.

The foregoing first to seventh experimental examples (Ex1 to Ex7) are based on a white light emitting device. In the display device, dielectric films with transistors may be added to a lower side of the emission portion of the white light emitting device. In the following examples, therefore, the efficiency and viewing angle characteristics of a white light emitting device of a display device configured to have a structure in which dielectric films are added to a lower side of the cathode and/or the optical compensation layer will be described.

In a first experimental modification (Ex1b), a first interlayer dielectric film INE1, a second interlayer dielectric film INE2, and a planarization layer OC, all of which are inorganic dielectric films, are further provided between the substrate SUB and the anode (ITO) of the white light emitting device of FIG. 6A. In a second experimental modification (Ex2b), a first interlayer dielectric film INE1, a second interlayer dielectric film INE2, and a planarization layer OC, all of which are inorganic dielectric films, are further provided between the substrate SUB and the cathode (ITO) of the white light emitting device of FIG. 6B.

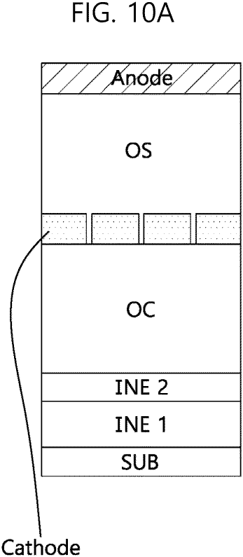

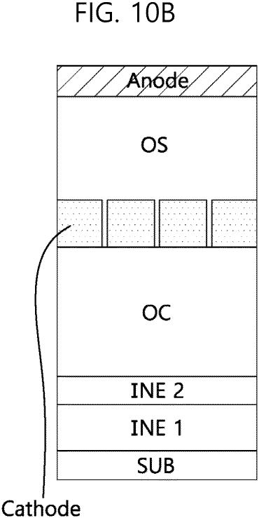

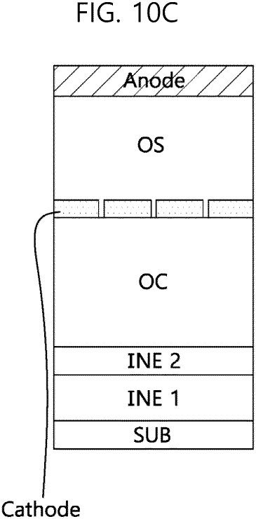

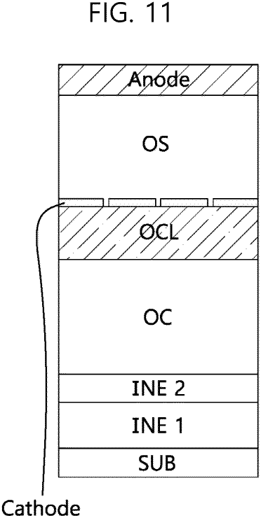

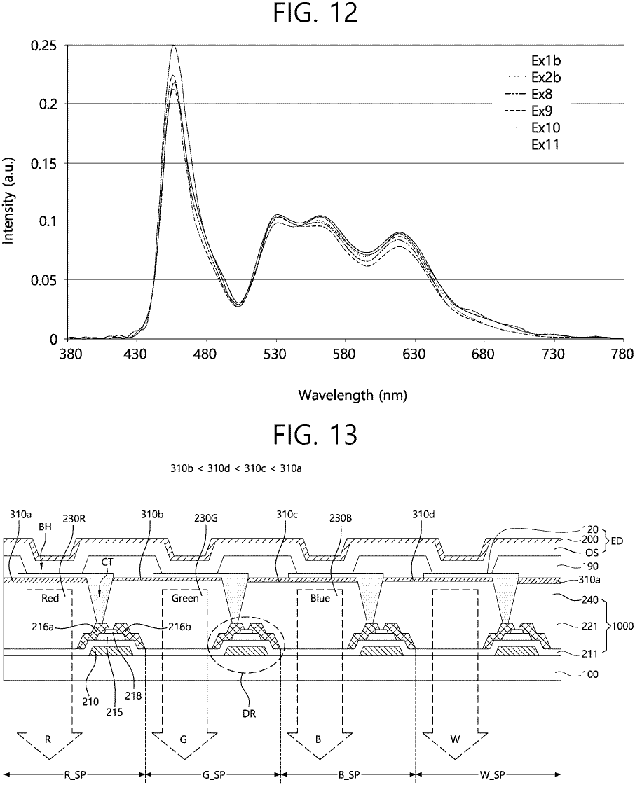

FIGS. 10A to 10C are examples of sectional views showing seventh to ninth experimental examples, FIG. 11 is an example of a sectional view showing a tenth experimental example, and FIG. 12 is an example of a graph showing the white spectra of the first and second experimental modification examples (Ex1a and Ex2a) and the seventh to tenth experimental examples (Ex7 to Ex10).

The seventh to ninth experimental examples (Ex8, Ex9, and Ex10) shown in FIGS. 10A to 10C provide white light emitting devices each having the same inverted structure as in FIG. 6B, except that they are different from each other in terms of the total thickness of the intermediate functional layer OS and the thickness of the cathode 20 abutting the substrate SUB, as in the third to fifth experimental examples described above. Furthermore, in each of the seventh to ninth experimental examples (Ex7, Ex8, and Ex9) shown in FIGS. 9A to 9C, a first interlayer dielectric film INE1, a second interlayer dielectric film INE2, and a planarization layer OC, all of which are inorganic dielectric films, are provided between the substrate SUB and the cathode (ITO).

As shown in FIG. 11, the inverted white light emitting device according to the tenth experimental example (Ex11) has a structure in which the intermediate functional layer OS shown in FIG. 1 is provided between a cathode Cathode and an anode Anode (200) and in which an optical compensation layer OCL is provided under the cathode Cathode so as to abut the cathode.

The first experimental modification (Ex1a) and the second experimental modification (Ex2b) are different from each other in terms of whether the white light emitting device has a normal structure or an inverted structure. In the first experimental modification (Ex1b), the lowest electrode is the anode, and a transparent electrode made of ITO is used as the anode. In the second experimental modification (Ex2b), the lowest electrode is the cathode, and a transparent electrode made of ITO is used as the cathode. In each of the first and second experimental modifications (Ex1b and Ex2b), the transparent electrode made of ITO, which is the lowest electrode, has a thickness of 1200 Å.

The thickness of the cathode and the thickness of the first electron transport layer abutting the cathode of each of the inverted white light emitting devices according to the second experimental modification (Ex2b) and the seventh to tenth experimental examples (Ex8 to Ex11) are shown in Table 2. In the second experimental modification (Ex2b), the thickness of the first electron transport layer is 910 Å, and the thickness of the cathode is 1200 Å. In the seventh experimental example (Ex8), the thickness of the first electron transport layer is 500 Å, and the thickness of the cathode is 1658 Å. In the seventh experimental example (Ex8), the thickness of the intermediate functional layer OS is decreased and the thickness of the cathode is increased, compared to the second experimental modification (Ex2b). In the eighth experimental example (Ex9), the thickness of the first electron transport layer ETL1 is 100 Å, and the thickness of the cathode (ITO) is 2090 Å. In order to reduce driving voltage, the thickness of the first electron transport layer ETL1 is decreased and the thickness of the cathode (ITO) is increased, compared to the seventh experimental example (Ex8). In the ninth experimental example (Ex10), the thickness of the first electron transport layer ETL1 is 100 Å, and the thickness of the cathode (ITO) is 440 Å. This experimental example is given to determine an optical change when the thickness of the cathode is reduced, compared to the eighth experimental example (Ex9).

The white light emitting device according to the tenth experimental example (Ex11) is different from the white light emitting device according to the ninth experimental example (Ex10) in that the thickness of the cathode is reduced and the optical compensation layer OCL is further included. The thickness of the first electron transport layer is 100 Å, the thickness of the cathode is 330 Å, and the thickness of the optical compensation layer OCL is 1580 Å.

In the seventh to tenth experimental examples (Ex8, Ex9, Ex10, and Ex11), a first interlayer dielectric film INE1, a second interlayer dielectric film INE2, and a planarization layer OC are disposed under the cathode (ITO), in the same manner as in the first experimental modification (Ex1a) and the second experimental modification (Ex2b).

The first interlayer dielectric film INE1 may be the gate dielectric film 211 of FIG. 2. Depending on the circumstances, a buffer layer may be further included. In an experiment, the first interlayer dielectric film INE1 was formed by stacking a silicon oxide (SiOx) film having a thickness of 3000 Å and a silicon nitride (SiNx) film having a thickness of 1000 Å. The second interlayer dielectric film INE2 may be the passivation film 221 of FIG. 2. In an experiment, the second interlayer dielectric film INE2 was made of SiOx having a thickness of 1800 Å. In addition, the thickness of the planarization layer OC was 2900 nm.

In addition, in Table 3, a driving voltage, a red efficiency (R efficiency), a green efficiency (G efficiency), a blue efficiency (B efficiency), and a white efficiency (W efficiency) of each of the experimental examples excluding the first experimental example (Ex1) are provided as relative values in relation to the first experimental modification (Ex1b).

TABLE 3

| | Structure (Thickness)[Å] | | | Driving voltage | R efficiency | G efficiency | B efficiency | W efficiency | Deviation of viewing |
|---|---|---|---|---|---|---|---|---|---|
| | ETL1 | ITO | OCL | | | | | | |
| Ex1b | 100 | 1200 [Anode] | - | 0 | 100 | 100 | 100 | 100 | 0.0285 |
| Ex2b | 910 | 1200 [Cathode] | - | +2.2 | 104 | 101 | 86 | 101 | 0.0285 |
| Ex8 | 500 | 1658 [Cathode] | - | 0 | 96 | 100 | 99 | 98 | 0.0247 |
| Ex9 | 100 | 2090 [Cathode] | - | -1.1 | 91 | 98 | 96 | 95 | 0.0193 |
| Ex10 | 100 | 440 [Cathode] | - | -1.1 | 104 | 98 | 109 | 101 | 0.0152 |
| Ex11 | 100 | 330 [Cathode] | 1580 | -1.1 | 106 | 103 | 103 | 104 | 0.0187 |

The results shown in Table 3 and FIG. 12 are obtained by having the dielectric films, which are included in the array 1000 of FIG. 2 or FIG. 3, in a white light emitting device as a structure in which the dielectric films are required in the white light emitting device of the display device. In this case, as shown in Table 3, the deviation of the viewing angle in each of the first experimental modification (Ex1b) and the second experimental modification (Ex2b) is greater than in the first and second experimental examples (Ex1 and Ex2), from which it can be expected that visibility due to the color deviation will become a problem when the normal white light emitting device and the inverted white light emitting device are actually implemented in the display device.

As shown in Table 3, in the second experimental modification example (Ex2b), in which the structure of the first experimental modification example (Ex1b) is inverted, the thickness of the first electron transport layer abutting the cathode is increased, whereby a driving voltage is increased by 2.2 V due to the increased thickness of the first electron transport layer and the low mobility of the first electron transport layer, compared to the first experimental modification example (Ex1b).

When the thickness of the cathode is increased, as in the eighth experimental example (Ex8), in order to solve the problem in that the driving voltage of the inverted white light emitting device according to the second experimental modification example (Ex2b) is increased, similar driving voltage characteristics as in the first experimental modification example (Ex1b) are achieved, but the red efficiency, blue efficiency, and white efficiency are lowered.

Meanwhile, it can be seen that, in the ninth to eleventh experimental examples (Ex9 to Ex11), in which the thickness of the first electron transport layer ETL1 is reduced to ⅕ of the thickness of the first electron transport layer in the eighth experimental example (Ex8), the driving voltage is lower by 1.1 V from that of the first experimental modification example (Ex1b) and the eighth experimental example (Ex8), whereby the driving voltage is reduced. However, it can be seen from Table 1 and FIG. 11 that, in the ninth experimental example (Ex9) and the tenth experimental example (Ex10), the color efficiency is lowered. In addition, in the tenth experimental example (Ex10), the green efficiency is decreased, whereas the blue efficiency is increased, whereby the color-specific defect may occur at the time of emitting white light.

In contrast, in the eleventh experimental example (Ex11), the optical compensation layer is provided under the cathode, whereby the cavity of the light that has passed through the cathode is compensated for by the optical compensation layer thereunder even though the thin cathode and the thin first electron transport layer are provided, and therefore light is emitted to the outside with high emission efficiency. Consequently, it can be seen that, in the eleventh experimental example (Ex11), the red, green, blue, and white efficiencies are higher than those of the normal white light emitting device according to the second experimental modification example (Ex1b) as well as the inverted white light emitting device according to the second experimental modification example (Ex2b). In addition, the red, green, blue, and white efficiencies are similarly improved, and thus the color-specific balance may be maintained at the time of emitting white light. Furthermore, in the eleventh experimental example (Ex11), the deviation of the viewing angle is 0.0187, and therefore it can be seen that the viewing angle is further improved compared to that of the white light emitting device excluding the dielectric films, described with reference to Table 1 and FIG. 8.

Hereinafter, a display device according to another example embodiment of the present disclosure will be described.

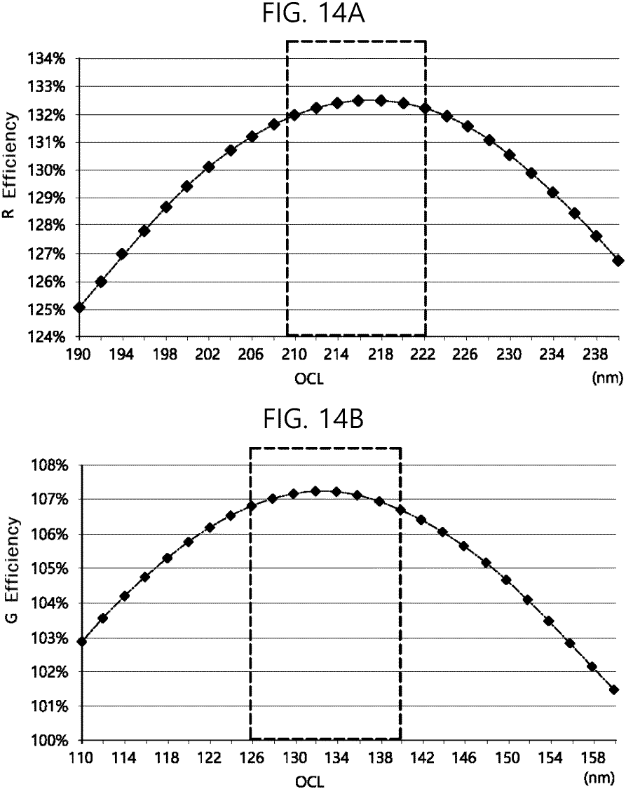

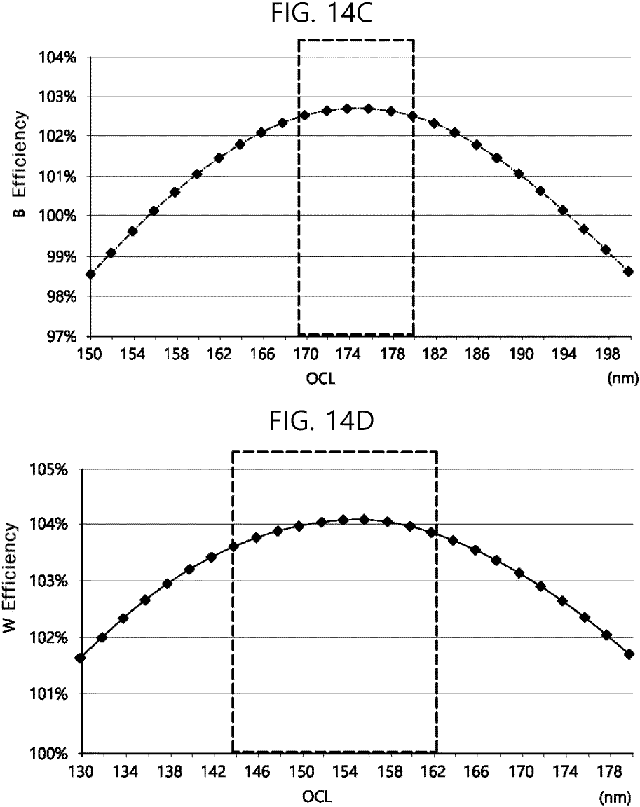

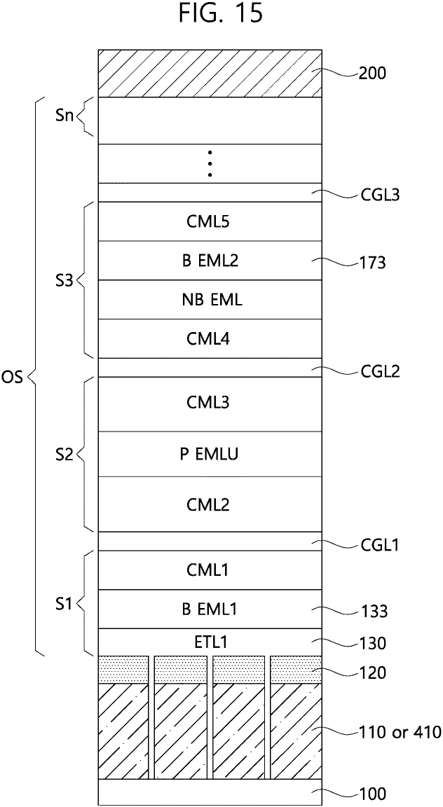

FIG. 13 is a sectional view showing a display device according to another example embodiment of the present disclosure, and FIGS. 14A to 14D are examples of graphs respectively showing the relationship between the red, green, blue, and white efficiencies and the thickness of an optical compensation layer.

In the display device according to the other example embodiment of the present disclosure shown in FIG. 13, an optical compensation layer is provided in each of subpixels that emits a different color so as to have an optimal cavity compensation effect.

As shown in FIG. 13, in the display device according to the other example embodiment of the present disclosure may have a plurality of subpixels, including a red subpixel R_SP, a green subpixel G_SP, a blue subpixel B_SP, and a white subpixel W_SP. The display device may include a substrate 100 and a planarization layer 240. The display device may further include a red conversion layer 230R, a green conversion layer 230G, and a blue conversion layer 230B (corresponding respectively to the red subpixel, the green subpixel, and the blue subpixel) between the planarization layer 240 and the substrate 100.

For each subpixel, a cathode 120 of a white light emitting device ED is connected to a drain electrode 216a of a driving transistor DR through a contact hole CT formed through the planarization layer 240 and a passivation film 221.

In the display device according to the other example embodiment of the present disclosure, optical compensation layers 310a, 310b, 310c, and 310d having different thicknesses are provided at the subpixels that emit different lights to provide an optimum compensation for the cavity with respect to each subpixel.

A description of the same parts as those in FIG. 2 may be omitted for brevity.

In FIGS. 14A to 14D, experiments are performed according to the eleventh experimental example (Ex11) shown in FIG. 11 using a silicon nitride film as each optical compensation layer, wherein the thickness of the optical compensation layer is changed to evaluate the color efficiency of each subpixel.

As shown in FIG. 14A, the red conversion layer is further provided under the optical compensation layer, wherein, when the thickness of the optical compensation layer is within a range from 190 nm (1900 Å) to 240 nm (2400 Å), the red efficiency of the red subpixel is improved by 125% or more, compared to the first experimental modification example (Ex1b). It can be seen that the efficiency is 132% or more within a range of 210 nm to 222 nm.

As shown in FIG. 14B, the green conversion layer is further provided under the optical compensation layer, wherein, when the thickness of the optical compensation layer is within a range from 110 nm (1100 Å) to 160 nm (1600 Å), the green efficiency of the green subpixel is improved by 101% or more, compared to the first experimental modification example (Ex1b). It can be seen that the efficiency is 106.8% or more within a range of 126 nm to 140 nm.

As shown in FIG. 14C, the blue conversion layer is further provided under the optical compensation layer, wherein, when the thickness of the optical compensation layer is within a range from 150 nm (1500 Å) to 200 nm (2000 Å), the blue efficiency of the blue subpixel is improved by 99% or more, compared to the first experimental modification example (Ex1b). It can be seen that the efficiency is 102.5% or more within a range of 170 nm to 180 nm.

As shown in FIG. 14D, the white subpixel has no color conversion layer, and has similar results as the eleventh experimental example (Ex11) shown in Table 3. That is, when the thickness of the optical compensation layer is within a range from 130 nm (1300 Å) to 180 nm (1800 Å), the efficiency of the white subpixel is improved by 101.6% or more, compared to the first experimental modification (Ex1a). It can be seen that the efficiency is 103.5% or more within a range of 144 nm to 162 nm.

As described above, the thicknesses of the optical compensation layers 310a, 310b, 310c, and 310d may be changed in order to achieve color subpixel-specific optimum efficiency. The thicknesses of the optical compensation layers 310a, 310b, 310c, and 310d may be changed for each color subpixel in order to achieve the optimum efficiency of each subpixel. In addition, the thicknesses of the optical compensation layers may be increased in thickness order of the green subpixel G_SP, the white subpixel W_SP, the blue subpixel B_SP, and the red subpixel R_SP (310b < 310d < 310c < 310a).

Meanwhile, FIGS. 14A to 14D show an example embodiment, wherein, when the thicknesses of the optical compensation layers are 1100 Å to 2400 Å, a color-specific cavity compensation effect for each subpixel may be achieved, and therefore the optical compensation layers may be formed so as to have the same thickness. Depending on the circumstances, two pixels, among the four subpixels, may have the same optical compensation layers, and the other two pixels may have the same optical compensation layers. Alternatively, the thicknesses of the optical compensation layers for three subpixels may be different from the thickness of the optical compensation layer for the other one subpixel.

In the structure in which the display device includes only the red, green, and blue subpixels without the white subpixel, the optical compensation layers may have different thicknesses for the three subpixels, or the optical compensation layers may have the same thickness for two subpixels.

FIG. 15 is a sectional view showing a white light emitting device according to another example embodiment of the present disclosure.

As shown in FIG. 15, the white light emitting device according to another example embodiment of the present disclosure represents an inverted white light emitting device and includes a cathode Cathode, an anode Anode and an intermediate functional layer OS having 4 or more stacks S1, S2, S3, ... Sn. In one or more aspects, n may be a natural number. In this example, n may be a natural number greater than three.

As shown in FIG. 15, the plurality of stacks S1, S2, S3, ... Sn may be divided by one or more charge generation layers CGL1, CGL2, CGL3, ... , therebetween. Each stack S1, S2, S3, ... Sn may include a light emitting layer. The first stack S1 may include a first blue light emitting layer B EML1 to emit a blue light. The second stack S2 may include a phosphorescent light unit P EMLU to emit a light having a wavelength greater (or longer) than that of the blue light. The phosphorescent light unit P EMLU may include a plurality of phosphorescent light emitting layers (or at least two phosphorescent light emitting layers), and the plurality of phosphorescent light emitting layers may be in contact with each other.

The phosphorescent light unit P EMLU may have a red light emitting layer, a yellow-green light emitting layer, and a green light emitting layer, as shown in FIG. 1.

As shown in FIG. 15, the third stack S3 may include a blue light emitting layer B EML2 and a non-blue light emitting layer NB EML in contact with the blue light emitting layer B EML2. In this case, the non-blue light emitting layer NB EML may increase the blue efficiency of the blue light emitting layer B EML2 and may adjust a white balance in the white light emitting device ED.

As shown in FIG. 15, in the third stack S3, the non-blue light emitting layer NB EML and the blue light emitting layer B EML2 may be formed in this order. Conversely, the blue light emitting layer B EML2 may be disposed at a lower side, and the non-blue light emitting layer NB EML may be located at an upper side.

An additional stack Sn may be added on the third stack S3 to compensate for insufficient color efficiency in a white light emitting device ED.

In FIG. 15, the optical compensation layer 110 or 410 has the same width as that of the cathode 120. However, it is not limited thereto. The width of the optical compensation layer 110 or 410 may have a width different from that of the cathode 120.

The optical compensation layer 110 or 410 may be a transparent dielectric film or a transparent electrode. The optical compensation layer 110 or 410 may have a refractive index that is greater than that of the cathode 120 by an amount which is in a range of 0.1 or more, and 0.4 or less.

In FIG. 15, CML1, CML2, CML3, CML4 and CML5 are common layers to transport electrons or holes. The common layers ETL1, CML2 and CML4 under the light emitting layers B EML1, P EMLU and NB EML are electron transport layers. The common layers CML1, CML3, and CML5 on the light emitting layers B EML1, P EMLU and B EML2 are hole transport layers. Also, in the stack Sn may include a charge transport layer contacting the light emitting layer therein. The charge transport layer includes at least one an electron transport layer and a hole transport layer.

The first electron transport layer 130 (ETL1) is located in the first stack S1 and controls a blue emission cavity. As shown in the sixth experimental example (Ex6) or the seventh experimental example (Ex7), since the first electron transport layer 130 (ETL1) can be formed with a thin thickness (such as a thickness of 100 Å), it is possible to reduce an entire thickness of the intermediate functional layer OS and reduce a driving voltage of the white light emitting device ED.

In the white light emitting device according to FIG. 15, the optical compensation layer 110 or 410 is provided below the cathode 120, so that a cavity compensation of the intermediate functional layer OS may be performed by the optical compensation layer 110 or 410. Furthermore, by reducing the thickness of the first electron transport layer 130 (ETL1) positioned below the first blue light emitting layer BEML1 in the first stack S1, it is possible to reduce an entire thickness of the intermediate functional layer OS. Therefore, the white light emitting device according to FIG. 15 may reduce the driving voltage of the white light emitting device ED and improve a blue efficiency with a white efficiency.

Examples of the optical compensation layers and the differences in thickness between the optical compensation layers for the subpixels have been described herein using the above experimental examples. When the internal construction of the white light emitting device is changed, the thicknesses of the optical compensation layers may be changed, as needed.

A white light emitting device according to one or more aspects of the present disclosure may comprise an optical compensation layer on a substrate, a cathode having a first surface abutting the optical compensation layer, an anode opposite to a second surface of the cathode, and an intermediate functional layer between the second surface of the cathode and the anode, the intermediate functional layer comprising a plurality of stacks divided by one or more charge generation layers. One of the stacks may be a first stack comprising a blue emission layer, and another stack may be a second stack comprising a plurality of emission layers to emit lights having different wavelengths longer than a wavelength of the blue emission layer, respectively.

In a white light emitting device and a display device using the same according to one or more aspects of the present disclosure, the first stack further includes an electron transport layer (e.g., 130), wherein the electron transport layer (which is not a hole transport layer) is adjacent to the cathode (e.g., 120) and is closer to the cathode than to the anode (e.g., 200). In one or more aspects, the foregoing configuration and position of the electron transport layer fulfill, and are vital to, one or more objects and purposes of the present disclosure as they can advantageously effectuate reducing the driving voltage of a display device and improving the efficiency and the viewing angles characteristics of the display device.

In a white light emitting device and a display device using the same according to one or more aspects of the present disclosure, the thickness of the electron transport layer (e.g., 130) adjacent to an inner surface of the cathode (e.g., 120) may be reduced to 500 Å or less. In one or more aspects, the thickness of the electron transport layer closest to the inner surface of the cathode may be, preferably, 50 Å or more and 500 Å or less. In one or more aspects, the foregoing configuration and thicknesses of the electron transport layer fulfill one or more objects and purposes of the present disclosure as they can advantageously effectuate reducing the driving voltage of a display device and improving the efficiency and the viewing angles characteristics of the display device.

In a white light emitting device and a display device using the same according to one or more aspects of the present disclosure, the thickness of the cathode (e.g., 120) is greater than or equal to the thickness of the electron transport layer (e.g., 130), which is located closer to the cathode than to the anode (e.g., 200). In one or more aspects, the foregoing configuration and thicknesses fulfill one or more critical aspects, objects and purposes of the present disclosure as they can advantageously effectuate reducing the driving voltage of a display device and improving the efficiency and the viewing angles characteristics of the display device.

In a white light emitting device and a display device using the same according to one or more aspects of the present disclosure, the electron transport layer (e.g., 130) is not a hole transport layer, wherein the cathode (e.g., 120) is closer to the electron transport layer than to the blue emission layer (e.g., 133), and wherein a thickness of the optical compensation layer (e.g., 110 or 410) is greater than a thickness of the cathode. In one or more aspects, the foregoing configurations and thicknesses fulfill one or more objects and purposes of the present disclosure as they can advantageously effectuate reducing the driving voltage of a display device and improving the efficiency and the viewing angles characteristics of the display device.

In a white light emitting device and a display device using the same according to one or more aspects of the present disclosure, a device, such as a display device, may comprise the white light emitting device and a non-white light emitting device, wherein the thickness of the optical compensation layer for the white light emitting device is different from a thickness of an optical compensation layer for the non-white light emitting device. In one or more aspects, having optical compensation layers with different thicknesses for the white and non-white light emitting devices can accomplish one or more objects and purposes of the present disclosure, including achieving optimum compensations for the cavities of the respective light emitting devices, and thus can effectuate reducing the driving voltage of a display device and/or improving the efficiency and/or the viewing angles characteristics of the display device.

In a white light emitting device and a display device using the same according to one or more aspects of the present disclosure, a display device may comprise a red subpixel, a green subpixel, a blue subpixel, and a white subpixel, wherein the white subpixel comprises the white light emitting device, wherein the thickness of the optical compensation layer for the white light emitting device is different from at least one of thicknesses of optical compensation layers at emission portions of the red subpixel, the green subpixel, and the blue subpixel. In one or more aspects, these specific configurations, in which the thickness of the optical compensation layer for the white light emitting device is different from at least one of the thicknesses of the optical compensation layers at the emission portions of the red, green, and blue subpixels, can accomplish one or more objects and purposes of the present disclosure, including achieving an optimum compensation for each respective cavity, and thus can effectuate reducing the driving voltage of a display device and/or improving the efficiency and/or the viewing angles characteristics of the display device.

In a white light emitting device and a display device using the same according to one or more aspects of the present disclosure, the anode and the intermediate functional layer are disposed in a recess having side walls, and the recess is at an emission portion of a subpixel.

In a white light emitting device and a display device using the same according to one or more aspects of the present disclosure, the white light emitting device is located in a subpixel, and the optical compensation layer is located at an emission portion of the subpixel but not at a non-emission portion of the subpixel.

In a white light emitting device and a display device using the same according to one or more aspects of the present disclosure, the optical compensation layer may be transparent. The optical compensation layer may be thicker than the cathode.

In a white light emitting device and a display device using the same according to one or more aspects of the present disclosure, the optical compensation layer may be a transparent dielectric film or a transparent electrode.

In a white light emitting device and a display device using the same according to one or more aspects of the present disclosure, the optical compensation layer may have a refractive index greater than a refractive index of the cathode.

In a white light emitting device and a display device using the same according to one or more aspects of the present disclosure, the optical compensation layer may have a refractive index equal to or greater than an average refractive index of the intermediate functional layer.

In a white light emitting device and a display device using the same according to one or more aspects of the present disclosure, the optical compensation layer may be a transparent electrode having a refractive index greater than a refractive index of the cathode.

In a white light emitting device and a display device using the same according to one or more aspects of the present disclosure, the optical compensation layer may be a silicon nitride film.

In a white light emitting device and a display device using the same according to one or more aspects of the present disclosure, the optical compensation layer (e.g., 110 or 410) may include one or more of silicon nitride and indium zinc oxide (IZO). In one or more examples, the optical compensation layer may be (or may include) a silicon nitride film or IZO.

A white light emitting device according to one or more aspects of the present disclosure may further comprise an organic dielectric film between the substrate and the optical compensation layer.

A white light emitting device according to one or more aspects of the present disclosure may further comprise a color conversion layer between the organic dielectric film and the substrate.

In a white light emitting device and a display device using the same according to one or more aspects of the present disclosure, light generated in the intermediate functional layer may be transmitted through the substrate via the cathode and the optical compensation layer.

In a white light emitting device and a display device using the same according to one or more aspects of the present disclosure, the cathode may comprise a transparent electrode having a thickness of 100 Å to 700 Å.

In a white light emitting device and a display device using the same according to one or more aspects of the present disclosure, the optical compensation layer may have a thickness of 1100 Å to 2400 Å.

In a white light emitting device and a display device using the same according to one or more aspects of the present disclosure, the intermediate functional layer may further comprise a third stack comprising a blue emission layer.

In a white light emitting device and a display device using the same according to one or more aspects of the present disclosure, the intermediate functional layer may further comprise a further stack comprising a blue emission layer and another color emission layer abutting the blue emission layer.

A display device according to one or more aspects of the present disclosure, may comprise a plurality of subpixels, each subpixel having an emission portion and a non-emission portion provided around the emission portion, a substrate (extending throughout the plurality of subpixels), a subpixel driving circuit at the non-emission portion of each subpixel of the plurality of subpixels, a planarization layer to cover the subpixel driving circuit, an optical compensation layer on the planarization layer to correspond to at least the emission portion of each subpixel, a cathode at each subpixel, the cathode having a first surface abutting the optical compensation layer, an anode opposite to a second surface of the cathode, and an intermediate functional layer between the second surface of the cathode and the anode, the intermediate functional layer comprising a plurality of stacks divided by one or more charge generation layers. One of the stacks may be a first stack comprising a blue emission layer, and another stack may be a second stack comprising one or more emission layers to emit one or more lights having one or more different wavelengths longer than a wavelength of the blue emission layer.

In a display device according to one or more aspects of the present disclosure, a thickness of the optical compensation layer at the emission portion of one of the plurality of subpixels is different from a thickness of the optical compensation layer at the emission portion of another one of the plurality of subpixels. In one or more aspects, having optical compensation layers with different thicknesses for different subpixels can accomplish one or more objects and purposes of the present disclosure, including achieving optimum compensations for the cavities of the respective subpixels, and thus can effectuate reducing the driving voltage of a display device and/or improving the efficiency and/or the viewing angles characteristics of the display device.

In a display device according to one or more aspects of the present disclosure, the first stack further comprises an electron transport layer, and the electron transport layer is adjacent to the cathode and is closer to the cathode than to the anode. In one or more aspects, the foregoing configuration and position of the electron transport layer fulfill one or more objects and purposes of the present disclosure as they can advantageously effectuate reducing the driving voltage of a display device and improving the efficiency and the viewing angles characteristics of the display device.

In a display device according to one or more aspects of the present disclosure, the thickness of the cathode is greater than or equal to a thickness of the electron transport layer. In one or more aspects, the foregoing configuration and thicknesses fulfill one or more objects and purposes of the present disclosure as they can advantageously effectuate reducing the driving voltage of a display device and improving the efficiency and the viewing angles characteristics of the display device.

In a display device according to one or more aspects of the present disclosure, for each of the plurality of subpixels, the cathode is closer to the electron transport layer than to the blue emission layer, and the thickness of the optical compensation layer at the emission portion is greater than a thickness of the cathode. In one or more aspects, the foregoing configurations and thicknesses fulfill one or more objects and purposes of the present disclosure as they can advantageously effectuate reducing the driving voltage of a display device and improving the efficiency and the viewing angles characteristics of the display device.

In a display device according to one or more aspects of the present disclosure, the anode and the intermediate functional layer are disposed in a recess having side walls, and the recess is at the emission portion of each subpixel of the plurality of subpixels.

In a display device according to one or more aspects of the present disclosure, the optical compensation layer of each subpixel may be transparent and may be thicker than the cathode. The optical compensation layer may be a transparent dielectric film or a transparent electrode.

In a display device according to one or more aspects of the present disclosure, the optical compensation layer of each subpixel may have a refractive index equal to or greater than an average refractive index of the intermediate functional layer of the corresponding subpixel.

In a display device according to one or more aspects of the present disclosure, the plurality of subpixels may comprise a red subpixel, a green subpixel, a blue subpixel, and a white subpixel. The display device may further comprise a red conversion layer, a green conversion layer, and a blue conversion layer corresponding respectively to the red subpixel, the green subpixel, and the blue subpixel between the corresponding planarization layer and the substrate.

In a display device according to one or more aspects of the present disclosure, at least two of the optical compensation layers at the emission portions of the red subpixel, the green subpixel, the blue subpixel, and the white subpixel have different thicknesses.

In a display device according to one or more aspects of the present disclosure, a thickness of the optical compensation layer at the emission portion of the green subpixel is less than a thickness of the optical compensation layer at the emission portion of the white subpixel; the thickness of the optical compensation layer at the emission portion of the white subpixel is less than a thickness of the optical compensation layer at the emission portion of the blue subpixel; and the thickness of the optical compensation layer at the emission portion of the blue subpixel is less than a thickness of the optical compensation layer at the emission portion of the red subpixel.

In a display device according to one or more aspects of the present disclosure, the subpixel driving circuit may comprise a driving transistor comprising a gate electrode on the substrate, a semiconductor layer, a gate dielectric film interposed between the semiconductor layer and the gate electrode, and a drain electrode and a source electrode provided at opposite sides of the semiconductor layer to be spaced apart from each other, wherein the drain electrode is connected to the cathode.

In a display device according to one or more aspects of the present disclosure, the optical compensation layer may electrically connect the driving transistor to the cathode.

In a display device according to one or more aspects of the present disclosure, for each subpixel of the plurality of subpixels, the drain electrode and cathode may be connected to each other through a common contact hole formed in the planarization layer and the optical compensation layer.

In a display device according to one or more aspects of the present disclosure, for each subpixel of the plurality of subpixels, the cathode may be a transparent electrode having a thickness of 100 Å to 700 Å, and the optical compensation layer at the emission portion may be a transparent dielectric film or a transparent electrode having a thickness of 1100 Å to 2400 Å.

In a display device according to one or more aspects of the present disclosure, the plurality of stacks of the intermediate functional layer may further comprise a third stack comprising a blue emission layer.

As is apparent from the above description, in one or more aspects, a white light emitting device according to an example embodiment of the present disclosure and a display device using the same have the following effects.

In the white light emitting device according to an example embodiment of the present disclosure and the display device using the same, an inverted white light emitting device is provided, and an optical compensation layer abutting a first surface (or an outer surface) of a cathode, through which light is emitted to the outside, is provided to compensate for the cavity of a stack structure in the white light emitting device. Since the optical compensation layer is provided, the thickness of an electron transport layer adjacent to a second surface (or an inner surface) of the cathode and the thickness of the cathode may be reduced, which can advantageously reduce the driving voltage of the white light emitting device and improve efficiency. In addition, the total thickness of the light emitting device structure between both electrodes (the cathode and the anode) to which the driving voltage is applied is reduced. This can reduce the deviation of the viewing angle and improve the image quality.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A white light emitting device, comprising:
an optical compensation layer on a substrate;
a cathode having a first surface abutting the optical compensation layer;
an anode opposite to a second surface of the cathode; and
an intermediate functional layer between the second surface of the cathode and the anode, wherein:
the intermediate functional layer comprises a plurality of stacks divided by one or more charge generation layers;
one of the plurality of stacks is a first stack comprising a blue emission layer and an electron transport layer;
another stack of the plurality of stacks is a second stack comprising a plurality of emission layers to emit lights having different wavelengths longer than a wavelength of the blue emission layer; and
the electron transport layer is adjacent to the cathode and is closer to the cathode than to the anode.

2. The white light emitting device according to claim 1, wherein the optical compensation layer is transparent and is thicker than the cathode.

3. The white light emitting device according to claim 1, wherein:
the cathode is closer to the electron transport layer than to the blue emission layer;
a thickness of the optical compensation layer is greater than a thickness of the cathode; and
the thickness of the cathode is greater than or equal to a thickness of the electron transport layer.

4. The white light emitting device according to claim 1, wherein the optical compensation layer has a refractive index greater than a refractive index of the cathode.

5. The white light emitting device according to claim 1, wherein the optical compensation layer has a refractive index equal to or greater than an average refractive index of the intermediate functional layer.

6. The white light emitting device according to claim 1, wherein the optical compensation layer is a transparent electrode having a refractive index greater than a refractive index of the cathode.

7. The white light emitting device according to claim 1, wherein the optical compensation layer comprises a silicon nitride film or an indium zinc oxide.

8. The white light emitting device according to claim 1, further comprising an organic dielectric film between the substrate and the optical compensation layer.

9. The white light emitting device according to claim 8, further comprising a color conversion layer between the organic dielectric film and the substrate.

10. The white light emitting device according to claim 1, wherein light generated in the intermediate functional layer is for being transmitted through the substrate via the cathode and the optical compensation layer.

11. The white light emitting device according to claim 2, wherein the cathode comprises a transparent electrode having a thickness of 100 Å to 700 Å.

12. The white light emitting device according to claim 2, wherein the optical compensation layer has a thickness of 1100 Å to 2400 Å.

13. The white light emitting device according to claim 1, wherein the intermediate functional layer further comprises a third stack comprising a blue emission layer.

14. The white light emitting device according to claim 1, wherein the intermediate functional layer further comprises a further stack comprising a blue emission layer and another color emission layer abutting the blue emission layer.

15. A display device, comprising:
a plurality of subpixels, each subpixel having an emission portion and a non-emission portion provided around the emission portion;
a substrate extending throughout the plurality of subpixels;
a subpixel driving circuit at the non-emission portion of each subpixel of the plurality of subpixels;
a planarization layer to cover the subpixel driving circuit;
an optical compensation layer on the planarization layer to correspond to at least the emission portion of each subpixel of the plurality of subpixels;
a cathode at each subpixel of the plurality of subpixels, the cathode having a first surface abutting the optical compensation layer;
an anode opposite to a second surface of the cathode; and
an intermediate functional layer between the second surface of the cathode and the anode, wherein:
the intermediate functional layer comprises a plurality of stacks divided by one or more charge generation layers;
one of the plurality of stacks is a first stack comprising a blue emission layer;
another stack of the plurality of stacks is a second stack comprising one or more emission layers to emit one or more lights having one or more different wavelengths longer than a wavelength of the blue emission layer; and
a thickness of the optical compensation layer at the emission portion of one of the plurality of subpixels is different from a thickness of the optical compensation layer at the emission portion of another one of the plurality of subpixels.

16. The display device according to claim 15, wherein:
the first stack further comprises an electron transport layer; and
the electron transport layer is adjacent to the cathode and is closer to the cathode than to the anode.

17. The display device according to claim 16, wherein with respect to each subpixel of the plurality of subpixels:
the cathode is closer to the electron transport layer than to the blue emission layer;
a thickness of the optical compensation layer at the emission portion is greater than a thickness of the cathode; and
the thickness of the cathode is greater than or equal to a thickness of the electron transport layer.

18. The display device according to claim 16, wherein a thickness of the electron transport layer is between 50 Å and 500 Å.

19. The display device according to claim 15, wherein, with respect to each subpixel of the plurality of subpixels, the optical compensation layer is a transparent dielectric film or a transparent electrode, and the optical compensation layer is thicker than the cathode.

20. The display device according to claim 15, wherein, with respect to each subpixel of the plurality of subpixels, a refractive index of the optical compensation layer is greater than a refractive index of the cathode, and is equal to or greater than an average refractive index of the intermediate functional layer.

21. The display device according to claim 15, wherein:
the plurality of subpixels comprise a red subpixel, a green subpixel, a blue subpixel, and a white subpixel; and
the display device further comprises a red conversion layer, a green conversion layer, and a blue conversion layer corresponding respectively to the red subpixel, the green subpixel, and the blue subpixel between the corresponding planarization layer and the substrate.

22. The display device according to claim 21, wherein at least two of the optical compensation layers at the emission portions of the red subpixel, the green subpixel, the blue subpixel, and the white subpixel have different thicknesses.

23. The display device according to claim 21, wherein:
a thickness of the optical compensation layer at the emission portion of the green subpixel is less than a thickness of the optical compensation layer at the emission portion of the white subpixel;
the thickness of the optical compensation layer at the emission portion of the white subpixel is less than a thickness of the optical compensation layer at the emission portion of the blue subpixel; and
the thickness of the optical compensation layer at the emission portion of the blue subpixel is less than a thickness of the optical compensation layer at the emission portion of the red subpixel.

24. The display device according to claim 15, wherein:
the subpixel driving circuit comprises a driving transistor comprising a gate electrode on the substrate, a semiconductor layer, a gate dielectric film interposed between the semiconductor layer and the gate electrode, and a drain electrode and a source electrode provided at opposite sides of the semiconductor layer to be spaced apart from each other; and
the drain electrode is connected to the cathode.

25. The display device according to claim 24, wherein:
the optical compensation layer electrically connects the driving transistor to the cathode.

26. The display device according to claim 24, wherein, with respect to each subpixel of the plurality of subpixels, the drain electrode and the cathode are connected to each other through a common contact hole formed in the planarization layer and the optical compensation layer.

27. The display device according to claim 15, wherein with respect to each subpixel of the plurality of subpixels:
the cathode is a transparent electrode having a thickness of 100 Å to 700 Å; and
the optical compensation layer is a transparent dielectric film or a transparent electrode having a thickness of 1100 Å to 2400 Å.

28. The display device according to claim 15, wherein the plurality of stacks of the intermediate functional layer further comprises a third stack comprising a blue emission layer.
